(19) United States
(12) Patent Application Publication
(10) Pub. No.: US 2008/0217748 A1
(43) Pub. Date: Sep. 11, 2008

(54) LOW COST AND LOW COEFFICIENT OF THERMAL EXPANSION PACKAGING STRUCTURES AND PROCESSES

(75) Inventor: John U. Knickerbocker, Monroe, NY (US)

Correspondence Address: CANTOR COLBURN LLP-IBM YORKTOWN, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/683,595

(22) Filed: Mar. 8, 2007

(51) Int. Cl. H01L 23/58

(52) U.S. Cl. 257/643

(57) ABSTRACT

A method for producing a chip carrier, the method includes selecting at least one core with a low coefficient of thermal expansion; selecting at least one build-up layer wherein each build-up layer includes a dielectric material and circuitry; and connecting selected cores and selected build-up layers together in a pre-determined order.

### TRADEMARKS

IBM® is a registered trademark of International Business Machines Corporation, Armonk, N.Y., U.S.A. Other names used herein may be registered trademarks, trademarks or product names of International Business Machines Corporation or other companies.

### BACKGROUND OF THE INVENTION

1. Field of the Invention

This invention relates to chip carriers.

2. Description of the Related Art

A semiconductor wafer may incorporate miniaturized devices such as electronic circuitry and optical devices. The miniaturized devices are referred to as silicon structures. An assembly of silicon structures is referred to as a silicon package. In general, an assembly of structures of various materials is referred to as a package. Typically, the silicon structures and silicon packages are mounted on a device known as a chip carrier. The chip carrier provides for connecting the silicon structures and silicon packages to other structures including printed wiring boards and other silicon structures and silicon packages.

As the density of the miniaturized devices increases, the power that must be dissipated by the silicon structures and silicon packages also increases. In general, the chip carrier provides for dissipating at least some of the power in the form of heat.

The chip carrier is generally fabricated from a substrate. Two primary types of substrate materials typically used are ceramic and organic. Ceramic and organic substrates have some limitations. Ceramic substrates can be higher in cost especially for high wiring density applications. One benefit of the ceramic substrates is that a coefficient of thermal expansion (CTE) can be matched to silicon at about 3 ppm. The CTE of the ceramic substrate may also be between the CTE of silicon and the CTE of an organic substrate (typically about 18 ppm).

In the prior art, four approaches are used to reduce or control thermal expansion of organic chip carriers (and some board materials) in a plane referred to as an X-Y plane. A first approach uses glass fibers in layers in a “central core” of the organic substrate or organic package such as flip chip carrier products. Glass fibers are not used in higher wiring density build up layers on either side of the central core. In this first approach, woven glass fibers having a lower CTE (typically under 18 ppm) reduce or maintain X-Y expansion and thereby force organic materials (which typically have the CTE in a range of 20 to 60 ppm depending on added fillers or chemistry) to expand more in a Z axis direction rather than the X-Y plane. In addition, use of copper wiring or power planes (CTE for copper is about 18 ppm) used in the organic package also manages the CTE and stresses in the X-Y plane. Although CTE expansion can be lowered to about 16 to 20 ppm in the first approach, the CTE expansion is still high compared to the CTE of silicon (about 3 ppm).

A second approach to reduce the CTE in the X-Y plane uses a metal core composed of a low CTE material such as invar or a clad such as copper-invar-copper in a central metal core. The central metal core has drilled holes or vias, Teflon organic dielectric insulation and copper wiring. In the second approach, the CTE may be reduced to about 12 ppm in X-Y plane. A limitation exists on a size and number of holes that can be made in a vertical direction directly under a surface mounted Silicon chip due to fine pitch wiring of about 200 μm pitch or somewhat less.

A third approach uses “thin film” organics as hybrid layers and a thick ceramic substrate. The hybrid layers may use polyimide as a dielectric and copper wiring. The thick ceramic substrate provides wiring at a coarse pitch. A few build-up or transferred layers on one side of the thick ceramic substrate (or package) can provide higher wiring density between die or off of die into the package. Cost has limited this approach primarily to multichip packaged modules for high integration and high performance applications.

A fourth approach uses glass fibers in each of multiple build-up layers in the organic packages to reduce the CTE of the composite structure to about 12 ppm. However, woven or embedded glass fibers cause concerns about electrical shorting of fine pitch wiring and vertical vias. Potential exists for electrical shorting due to glass to organic separations and migrations of conductor shorts. As a pitch between vertical connections is reduced, reliability of this approach decreases.

High mechanical stress levels in connections between the silicon structure and an organic chip carrier can result from a mismatch between the CTE of the silicon structure and the CTE of the organic chip carrier. The mismatch may occur when using one or combinations of the following: (i) larger silicon structure sizes (such as greater than 10 mm to 20 mm on a side), (ii) use of less ductile solders such as lead free solders (Sn—Ag—Cu alloy family compared to Pb—Sn alloy family), (iii) use of lower strength or modulus materials in a silicon structure (such as for low K dielectrics used for improved electrical performance), and (iv) when reducing a size or pitch of area array or perimeter interconnections from the silicon structure to the organic package (such as interconnections of 100 μm diameter and 200 μm pitch to smaller size and pitch). The high mechanical stress levels can cause failures due to thermal excursions in areas such as the silicon structures, the interconnections between the silicon structure and the chip carrier, between two packages (such as the silicon package and the organic package), and within the silicon package itself especially for large size silicon structures and silicon packages (typically greater than 10 mm length on a side).

What are needed are a chip carrier and package with a low coefficient of thermal expansion, which can support area array and peripheral interconnections and a process to fabricate the chip carrier and package. In particular, the chip carrier and package are needed to maintain a planar surface for mounting.

### SUMMARY OF THE INVENTION

The shortcomings of the prior art are overcome and additional advantages are provided though a method for producing a chip carrier, the method includes selecting at least one core with a low coefficient of thermal expansion; selecting at least one build-up layer wherein each build-up layer includes a dielectric material and circuitry; and connecting selected cores and selected build-up layers together in a pre-determined order.

Also disclosed is a chip carrier including at least one core with a low coefficient of thermal expansion, at least one via and at least one of a borosilicate glass, invar, molybdenum, and cordierite; and at least one build-up layer comprising an organic polymer and circuitry, wherein the circuitry comprises at least one of copper conductors and optical devices, and wherein each core and each build-up layer are connected together in a pre-determined order.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### Technical Effects

As a result of the summarized invention, technically we have achieved a solution with a method for producing a chip carrier, the method includes selecting at least one core with a low coefficient of thermal expansion; selecting at least one build-up layer wherein each build-up layer includes a dielectric material and circuitry; and connecting selected cores and selected build-up layers together in a pre-determined order.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 illustrates an exemplary embodiment of a laminated chip carrier with a low CTE central core and two build-up layers;

FIG. 2 illustrates an exemplary embodiment of the laminated chip carrier including two low CTE surface cores and one central build-up layer; and

FIG. 3 presents an exemplary flow diagram of a method for fabricating the laminated chip carrier with low CTE organic layers.

The detailed description explains the preferred embodiments of the invention, together with advantages and features, by way of example with reference to the drawings.

### DETAILED DESCRIPTION OF THE INVENTION

The teachings herein provide a process for producing a laminated chip carrier with a low coefficient of thermal expansion (CTE). Typically, the low CTE is less than or equal to 12 ppm (parts per million). The process typically includes laminating alternating layers of a core material and three-dimensional circuitry. The core material provides a supporting structure with a low CTE. The low CTE provides for less stress to larger silicon structures and silicon based packages connected to the laminated chip carrier that may include low CTE organic layers. The three-dimensional circuitry is provided by layers of an insulating dielectric material that includes conductors. In general, the three-dimensional circuitry can be laminated to the core material. Typically, a thinned core material (such as but not limited to thinned glass with vertical connections) includes conductive vias to provide for electrical conduction through the core material. The conductive vias provide a high interconnection density. The conductive vias may be used for at least one of signal connections, power connections, and ground. In embodiments with glass or ceramic cores, the conductive vias may be made of copper, tungsten, or an alternate electrically conductive material. For low CTE cores with metallic surfaces, vertical holes and surfaces are coated with a dielectric material to insulate electrical connections such as vias with metal conductors. Before the process and the laminated earlier are discussed in detail, certain definitions are provided.

The term “silicon structure” relates to a semiconductor chip or die in addition to the miniature electronic devices discussed above. The term silicon structure may also relate to a package or combination of semiconductor chips or die such as chip stacks. The term “chip carrier” relates to a platform upon which integrated circuits, optical devices, device encapsulants, embedded devices and thermal enhancement hardware are attached. Typically, both sides of the chip earlier provide for electrical connections. The chip carrier may be used to connect the integrated circuits and optical devices to other silicon structures and supporting substrates such as printed wiling boards. The term “conductive vias” relates to holes in the core material. Typically, the holes have a surface metallization to provide for electrical conduction. The holes may be formed by at least one of laser drilling, mechanical punch, photolithography, and reactive ion etching. The vias may be formed when the core material is in one of a pre-finished state and a finished state. The finished state provides for more precise locations of the vias than the pre-finished state. Via conductor metallization may be formed using copper plating or chemical vapor deposition of tungsten or alternate electrical conductors. The surface metallization may be provided by at least one of copper plating and chemical vapor deposition using tungsten. The term “build-up layer” relates to layers of an insulating material that includes conductors. Three-dimensional circuitry is fabricated by building up (i.e., attaching) layers together. One high density wiring build-up layer may include several layers of the insulating material that includes conductors. The build-up layers may be built directly on the low CTE cores or can be built separately and joined to the low CTE cores. The embedded devices may be attached to the low CTE core, embedded in organic build-up layers during assembly, or embedded in the “build up layers” during their fabrication.

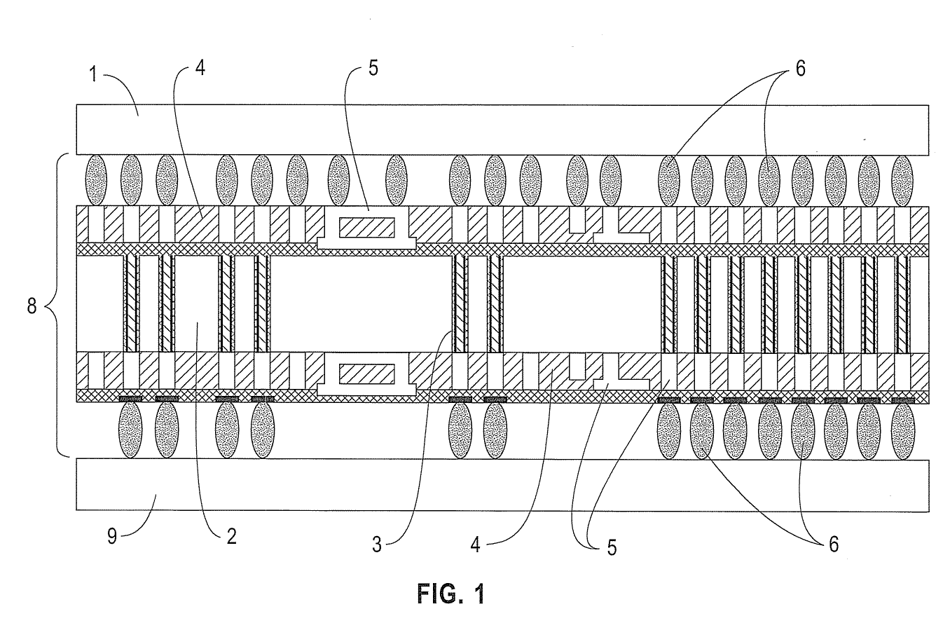

FIG. 1 illustrates an exemplary embodiment of a laminated chip carrier 8 with a core 2 and two build-up layers 4. The laminated chip carrier 8 provides for interconnecting a silicon structure 1 to a substrate 9. In other embodiments, the laminated chip carrier 8 may provide for interconnecting the silicon structure 1 to at least one of a chip and a board. The silicon stricture 1 may also represent a chip, a chip stack, or a silcon package with one or more die or die stacks. The substrate 9 may also represent at least one of the silicon structure 1, the silicon package, or the board. The build-up layers 4 typically include three-dimensional circuitry 5. The three-dimensional circuitry 5 typically includes wiring and a dielectric material. Connections between the silicon structure 1 and the substrate 9 are provided for by interconnections 6, the three-dimensional circuitry 5, and conductive vias 3. Typically, the interconnections 6 are at least one of solder and copper. The core 2 provides a low CTE in planar directions also referred to as an X-Y plane. The core 2 provides mechanical constraint in the X-Y plane for the build-up layers 4. For example, the core 2 with a low CTE of about two to four ppm or intermediate CTE of five to eight ppm may be attached to the build-up layers 4 having a CTE of about eighteen ppm. The laminated chip carrier 8 has a resulting CTE of about three to twelve ppm in the X-Y plane depending on relative material thicknesses of the core 2, build-up layer 4, and three-dimensional circuitry 5.

Referring to FIG. 1, exemplary embodiments of the core 2 may include low CTE glass such as borosilicate glass, liquid crystal display glass, thin ceramics, or glass ceramics such as cordierite, mullite, or alumina. The core 2 may provide several functions. For example, the core 2 may also provide planarity for purposes of joining the laminated carrier 8 to the silicon structure 1, the silicon package, electronic cards, and connections using at least one edge insertion of the laminated carrier 8. The core 2 may provide support for the silicon structures 1 with low mechanical strength. The core 2 in embodiments using glass may provide for optical communications by use of integrated optical waveguides in one of the glass and a surface of the glass. The use of glass for the core 2 may provide for edge connections on at least one surface for at least one of electrical and optical connections. The low CTE glass may be used to provide a hermetic seal when used with a seal to at least one of the silicon structure 1, the silicon package, and hardware.

Mechanical properties of the low CTE glass or ceramic may be enhanced by use of compressive stress surface layers. The glass or ceramic may also be placed into compression by organic build-up layers if joined at elevated temperature to improve structural integrity of the laminated chip carrier 8. Additionally, a polymer may be used to encapsulate the core 2. Further, vias filled with a polymer may be used to provide a mechanical interlock with the build-up layers 4 and the cores 2. The core 2 may be fabricated as one contiguous piece and subsequently segmented by laser or dicing. The core 2 may also be fabricated into the build-up layers 4 during fabrication of the build-up layers 4.

In some embodiments of the core 2 using glass, a liquid crystal display (LCD) may be integrated into the core 2. Other devices that may be integrated into the core 2 for two-dimensional and three-dimensional applications include the silicon structure 1 and the silicon package.

Referring to FIG. 1, each of the build-up layers 4 in certain embodiments includes copper conductors for the three-dimensional circuitry 5 attached to an organic polymer such as polyimide. Other embodiments of the build-up layers 4 include copper conductors for the three-dimensional circuitry 5 attached to glass. Using the build-up layers 4 provides for lower stress of the three-dimensional circuitry 5. The build-up layers 4 may be attached to the core 2 by at least one of adhesive, an adhesion layer, and the mechanical interlocks discussed above.

In certain embodiments, the conductive vias 3 may include at least one of surface metallization and conductive fill for electrical conduction. The surface metallization and conductive fill may be at least one of copper and tungsten.

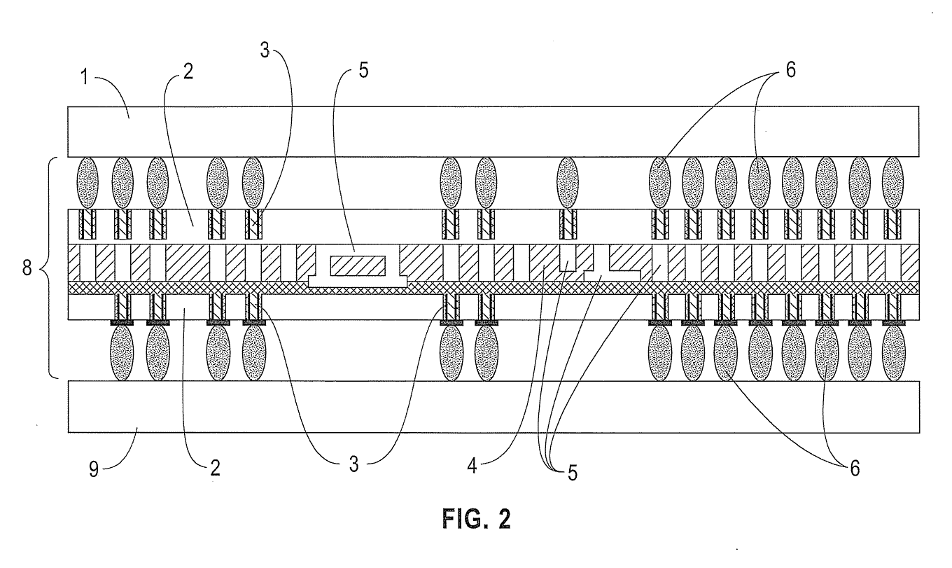

Any number of configurations of the laminated chip carrier 8 are possible employing the teachings herein. For example, FIG. 2 illustrates an exemplary embodiment of the laminated chip carrier 8 including two cores 2 and one build-up layer 4. The cores 2 may be low CTE surface cores. The low CTE surface cores may be either glass, ceramic, or metal such as invar or molybdenum. Two low CTE surface cores maintain planarity of the laminated chip carrier 8 for connection to another surface such as the silicon structure 1, the silicon package, or the board. The two low CTE surface cores on or near the top and bottom surfaces of the laminated chip carrier 8 maintain a more rigid and non-warping structure compared to high volume organic packages fabricated with a central core containing glass fibers. Glass or ceramic low CTE surface cores may be coated with a polymer for at least one of handling and adhesion to the conductors or the build-up layers 4. The glass or ceramic low CTE surface cores may also have the conductors and the dielectric material built directly on a surface for a layered or laminated package.

Referring to FIG. 2, in some embodiments of the cores 2 using the low CTE surface cores that include metal, the conductive vias 3 are insulated form the surrounding core 2 by a dielectric insulator.

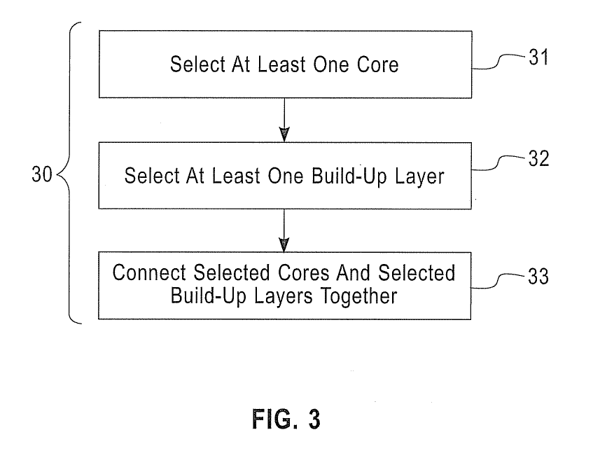

FIG. 3 presents an exemplary flow diagram of a method 30 for fabricating the laminated chip earlier 8. A first step 31 calls for selecting at least one core 2 with a low coefficient of thermal expansion. Typically, the core 2 may have the build-up layers 4 on one or both sides. In general, the first step 31 includes selecting a material, thickness, and size for the selected cores 2. The number of cores 2 and the material, thickness, and size may result from a design analysis. The design analysis may include determining among other factors an amount of structural rigidity required to support at least one of the silicon structure 1, the silicon package, and the LCD. A second step 32 calls for selecting at least one build-up layer 4. In general, the second step 32 may include selecting a number of layers included in each build-up layer 4 and the thickness, size, and material of each build-up layer 4. Also in general, the number of build-up layers 4, the number of layers in each build-up layer 4, the thickness, size and material of each build-up layer 4 results from the three-dimensional circuitry 5 required to connect to at least one of the silicon structure 1, the silicon package, the LCD, and the substrate 9. The three-dimensional circuitry 5 may include at least one of embedded silicon active or passive die (or circuitry), optical circuitry and optical devices. In general, the design analysis will analyze the requirements of the three-dimensional circuitry 5 and provide information for the second step 32. In one exemplary embodiment, the build-up layer 4 is fabricated on a handler to maintain planarity and alignment of connection features. The handler is then removed before the build-up layer 4 is connected to the core 2. In another embodiment, the build-up layer 4 is fabricated with glass fibers to maintain planarity and alignment of the connection features. A third step 33 calls for connecting selected cores 2 and selected build-up layers 4 together in a pre-determined order. In general, the pre-determined order is determined by the design analysis. Typically, the connecting includes laminating using at least one of an adhesive, an adhesive layer, and mechanical interlocks. As an alternative, the third step 33 may call for sequentially building up (or fabricating) the selected cores 2 and the selected build-up layers 4 connected together in accordance with the pre-determined order. The third step 33 typically includes maintaining alignment between the selected cores 2 and the build-up layers 4 to insure proper connections between the conductive vias 3, the three-dimensional circuitry 5, and the interconnections 6.

The flow diagrams depicted herein are just examples. There may be many variations to these diagrams or the steps (or operations) described therein without departing from the spirit of the invention. For instance, the steps may be performed in a differing order, or steps may be added, deleted or modified. All of these variations are considered a part of the claimed invention.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. A method for producing a chip carrier, the method comprising:
selecting at least one core comprising a low coefficient of thermal expansion;
selecting at least one build-up layer wherein each build-up layer comprises a dielectric material and circuitry; and
connecting selected cores and selected build-up layers together in a pre-determined order.

2. The method as in claim 1, wherein connecting comprises sequentially building the selected cores and the selected build-up layers connected together in accordance with the pre-determined order.

3. The method as in claim 1, wherein connecting comprises laminating with at least one of an adhesive, an adhesive layer and mechanical interlocks.

4. A chip carrier comprising:
at least one core comprising a low coefficient of thermal expansion (CTE), at least one via, and at least one of a glass, a borosilicate glass, invar, molybdenum, and cordierite; and
at least one build-up layer comprising an organic polymer and circuitry, wherein the circuitry comprises at least one of copper conductors and optical devices, and wherein each core and each build-up layer are connected together in a pre-determined order.

5. The chip carrier as in claim 4, further comprising at least one of embedded active and passive circuits.

6. The chip carrier as 1 claim 4, further comprising two cores, the cores comprising a surface, the surface comprising a thickness less than 730 micrometers and a low CTE.

7. The chip carrier as in claim 4, wherein the at least one via comprises at least one of:
surface metallization comprising at least one of copper and tungsten;
conductive fill comprising at least one of copper, tungsten; and metallic conductors; and
a mechanical interlock comprising a polymer.
